(19) United States
(12) Patent Application Publication
(10) Pub. No.: US 2025/0007110 A1
(43) Pub. Date: Jan. 2, 2025

(54) OVERMOLDED BUSBARS AND INTEGRATED SENSORS

(71) Applicant: Atieva, Inc., Newark, CA (US)

(72) Inventors: Bai Shao, Fremont, CA (US); Eric Magnus Bach, Los Altos Hills, CA (US); James Hawkins, Fremont, CA (US); Shun-Cheng Hung, Taipei City (TW); Cheng-Hung Lee, Taipei City (TW); Yung-Chuan Chien, New Taipei City (TW); Mingkai Mu, Fremont, CA (US)

(21) Appl. No.: 18/704,360

(22) PCT Filed: Oct. 26, 2022
(86) PCT No.: PCT/US2022/078705

§ 371 Date: Apr. 24, 2024

Related U.S. Application Data
(60) Provisional application No. 63/263,094, filed on Oct. 27, 2021.

(51) Int. Cl. H01M 50/524; B29C 45/14; B29L 31/30; B29L 31/34; B60R 16/03; H01M 50/249; H01M 50/507; H01M 50/519

(52) U.S. Cl. CPC H01M 50/524; B29C 45/14467; B29C 45/14639; B60R 16/03; H01M 50/249; H01M 50/507; H01M 50/519; B29L 2031/30; B29L 2031/3493; H01M 2220/20

(57) ABSTRACT

A vehicle may include a plurality of separate and distinct electrical busbars that are electrically isolated from each other. A device may include a polymer overmold material that mechanically couples the separate and distinct electrical busbars to each other in a single integrated multi-busbar unit, wherein the overmold material is provided to the busbars through an injection molding process. A device may include a flex printed circuit board having a plurality of sensors that is coupled to the single integrated multi-busbar unit, wherein the sensors are coupled to the distinct electrical busbars when the flex printed circuit board is coupled to the integrated busbar unit.

### CROSS-REFERENCE TO RELATED APPLICATION

This application claims priority to U.S. Provisional Patent Application No. 63/263,094, filed on Oct. 27, 2021, and entitled “OVERMOLDED BUSBARS AND INTEGRATED SENSORS,” the disclosure of which is incorporated by reference herein in its entirety.

### TECHNICAL FIELD

This disclosure relates to electrical busbars and, in particular, to a high voltage junction box (HVJB) that can be coupled to a battery module, where the HVJB includes overmolded busbars having integrated sensors.

### BACKGROUND

In recent years, the world's transportation has begun a transition away from powertrains primarily driven by fossil fuels and toward more sustainable energy sources, chiefly among them electric motors powered by on-board energy storages. In order to make these new modes of transportation available to larger segments of population, vehicle makers are striving to reduce the cost of manufacturing, including the cost of assembling battery packs to power electric motors.

### SUMMARY

In some aspects, a vehicle includes: a plurality of separate and distinct electrical busbars that are electrically isolated from each other; a polymer overmold material that mechanically couples the separate and distinct electrical busbars to each other in a single integrated multi-busbar unit, wherein the overmold material is provided to the busbars through an injection molding process; a flex printed circuit board having a plurality of sensors that is coupled to the single integrated multi-busbar unit, wherein the sensors are coupled to the distinct electrical busbars when the flex printed circuit board is coupled to the integrated busbar unit.

Implementations can include one or more of the following features, alone or in any combination with each other.

For example, the sensors can include a least one temperature sensor configured for measuring a temperature of at least one of the separate and distinct electrical busbars.

For example, the sensors can include at least one voltage sensor configured for measuring a voltage of at least one of the separate and distinct electrical busbars relative to a ground voltage.

For example, the sensors can include at least one strain gauge configured for measuring a mechanical property of at least one of the separate and distinct electrical busbars.

For example, the flex printed circuit board can include a ribbon cable configured to establish electrical connections between the plurality of sensors and an off-board controller.

For example, the busbars can be are part of a high voltage junction box.

For example, the vehicle can include a battery module having a plurality of electrochemical cells, where the separate and distinct electrical busbars are configured for conducting electricity to the electrochemical cells.

In some aspects, an apparatus includes: a plurality of separate and distinct electrical busbars that are electrically isolated from each other; and a polymer overmold material that mechanically couples the separate and distinct electrical busbars to each other in a single integrated multi-busbar unit, wherein the overmold material is provided to the busbars through an injection molding process; wherein the single integrated multi-busbar unit is configured to be coupled to a flex printed circuit board having a plurality of sensors, such that the sensors are coupled to the distinct electrical busbars when the flex printed circuit board is coupled to the integrated busbar unit.

Implementations can include one or more of the following features, alone or in any combination with each other.

For example, the polymer overmold material can include a plurality of receptacles configured for receiving the plurality of sensors.

For example, the sensors can include a least one temperature sensor configured for measuring a temperature of at least one of the separate and distinct electrical busbars.

For example, the sensors can include at least one voltage sensor configured for measuring a voltage of at least one of the separate and distinct electrical busbars relative to a ground voltage.

For example, the sensors can include at least one strain gauge configured for measuring a mechanical property of at least one of the separate and distinct electrical busbars.

For example, the busbars can be part of a high voltage junction box.

For example, the electrical busbars can include a plurality of holes configured for fastening the integrated multi-busbar unit to another component of the high voltage junction box.

In some aspects, a method of making an integrated multi-busbar unit includes: placing a plurality of separate and distinct electrical busbars into a mold cavity; injecting molten polymer material into the mold cavity, setting the polymer material in the mold cavity, such that the set polymer material bonds to the separate and distinct electrical busbars and the separate and distinct electrical busbars are rigidly held in place in a configuration in which the separate and distinct electrical busbars are electrically isolated from each other, wherein, after the polymer material is set, the integrated multi-busbar unit is configured to be coupled to a flex printed circuit board having a plurality of sensors, such that the sensors are coupled to the distinct electrical busbars when the flex printed circuit board is coupled to the integrated busbar unit.

Implementations can include one or more of the following features, alone or in any combination with each other.

For example, the set polymer overmold material can include a plurality of receptacles configured for receiving the plurality of sensors.

For example, the electrical busbars can include a plurality of holes configured for fastening the integrated multi-busbar unit to another component.

### BRIEF DESCRIPTION OF DRAWINGS

FIG. 1 is a schematic perspective view of an example vehicle.

FIG. 2 is a schematic perspective view of an example arrangement of a plurality of separate busbars that can be integrated into a modular component during production for assembly into a vehicle.

FIG. 3 is an example schematic diagram of the busbars of FIG. 2 mechanically connected to each other after they have been overmolded with a polymer material.

FIG. 4 is a schematic diagram of the overmolded busbars shown in FIG. 3 when a flexible printed circuit board (“flex PCB”) is attached to the busbars.

### DETAILED DESCRIPTION

This document describes examples of systems and techniques for manufacturing a HVJB using a housing to which a busbar is attached by overmolding the busbar with a polymer material and integrating a plurality of sensors with the busbar. Such approaches can simplify the production of the battery module and its associated busbar by reducing the number of components (e.g., sensors) that must be individually coupled to the busbar.

Examples herein refer to a battery module, which is an individual component configured for holding and managing multiple electrochemical cells during charging, storage, and use. The battery module can be intended as the sole power source for one or more loads (e.g., electric motors), or more than one battery module of the same or different type can be used. Two or more battery modules can be implemented in a system separately or as part of a larger energy storage unit. For example, a battery pack can include two or more battery modules of the same or different type. A battery module can include control circuitry for managing the charging, storage, and/or use of electrical energy in the electrochemical cells, or the battery module can be controlled by an external component. For example, a battery management system can be implemented on one or more circuit boards (e.g., a printed circuit board). In some implementations, a battery module can be connected to a HVJB that includes control circuitry for managing the charging, storage, and/or use of electrical energy in the electrochemical cells, or the battery module can be controlled by an external component. For example, a battery management system can be implemented on one or more circuit boards (e.g., a printed circuit board) in the HVJB.

Examples herein refer to electrochemical cells. An electrochemical cell can include an electrolyte and two electrodes to store energy and deliver it when used. In some implementations, the electrochemical cell can be a rechargeable cell. For example, the electrochemical cell can be a lithium-ion cell. In some implementations, the electrochemical cell can act as a galvanic cell when being discharged, and as an electrolytic cell when being charged. The electrochemical cell can have at least one terminal for each of the electrodes. The terminals, or at least a portion thereof, can be positioned at one end of the electrolytic cell. For example, when the electrochemical cell has a cylindrical shape, one of the terminals can be provided in the center of the end of the cell, and the can that forms the cylinder can constitute the other terminal and therefore be present at the end as well. Other shapes of electrochemical cells can be used, including, but not limited to, prismatic shapes.

Examples herein refer to molding, which is a process of forming a liquid or pliable material into a shape using a mold. Injection molding is a type of molding process where molten material is injected into the mold cavity. Overmolding refers to a molding operation where one or more parts are first placed inside the mold, and thereafter the molten material is introduced into the mold. This allows the molten material to be brought into contact with the part during the molding process so the part becomes joined to the finished molded component.

Examples herein refer to molding with a polymer material, which is a thermoplastic or thermosetting substance suitable for molding. The polymer material will be selected with properties such that the resulting component has suitable characteristics for the intended use. For example, a polymer material being molded into a housing to hold electrochemical cells should in its finished state have appropriate strength and stiffness considering the weight of the cells and its application, and also appropriate thermal and electrical properties in view of the charging, storage, and/or use of the electrochemical cells. Polycarbonate is an example of a polymer that can be molded into a housing for electrochemical cells. A polycarbonate material contains carbonate groups and is typically a good insulator and is resistant to heat and flames. One or more other materials can be added to the polymer material before the molding to change one or more of its properties. In some implementations, a polycarbonate material can have one or more additives. For example, strands of glass and/or another material can be added to polycarbonate or another polymer material.

Examples herein refer to a busbar, and a battery module can have at least one busbar. The busbar is electrically conductive and is used for conducting electricity to the electrochemical cells when charging, or from the cells when discharging. The busbar is made of an electrically conductive material (e.g., metal) and has suitable dimensions considering the characteristics of the electrochemical cells and the intended use. In some implementations, the busbar includes aluminum (e.g., an aluminum alloy). A busbar can be planar (e.g., flat) or can have one or more bends, depending on the shape and intended use of the battery module.

Examples described herein refer to a vehicle. As used herein, a vehicle is a machine that transports passengers or cargo, or both. A vehicle can have one or more motors using at least one type of fuel or other energy source (e.g., electricity). Examples of vehicles include, but are not limited to, cars, trucks, and buses. The number of wheels can differ between types of vehicles, and one or more (e.g., all) of the wheels can be used for propulsion of the vehicle. The vehicle can include a passenger compartment accommodating one or more persons. A vehicle can be powered by one or more types of power sources. In some implementations, a vehicle is powered solely by electricity, or can use one or more other energy sources in addition to electricity, to name just a few examples.

As used herein, the terms “electric vehicle” and “EV” may be used interchangeably and may refer to an all-electric vehicle, a plug-in hybrid vehicle, also referred to as a PHEV, or a hybrid vehicle, also referred to as a HEV, where a hybrid vehicle utilizes multiple sources of propulsion including an electric drive system.

Examples herein refer to a vehicle chassis. A vehicle chassis is a framework that bears the load of the rest of the vehicle. A vehicle chassis can include one or more frames, which can be made of steel, aluminum alloy, or another stiff and strong material. For example, a vehicle chassis is sometimes made of at least two side rails connected by multiple cross members for structural integrity. One or more other components, including, but not limited to, a battery pack for an electric or hybrid vehicle, can be integrated into or otherwise combined with a vehicle chassis. A subframe is a chassis portion that can carry certain components, including but not limited to, a motor, drivetrain, or suspension, to spread chassis loads and/or isolate vibrations and harshness.

Examples herein refer to a vehicle body. A vehicle body is the main supporting structure of a vehicle to which components and subcomponents are attached. In vehicles having unibody construction, the vehicle body and the vehicle chassis are integrated into each other. As used herein, a vehicle chassis is described as supporting the vehicle body also when the vehicle body is an integral part of the vehicle chassis. The vehicle body often includes a passenger compartment with room for one or more occupants; one or more trunks or other storage compartments for cargo; and various panels and other closures providing protective and/or decorative cover.

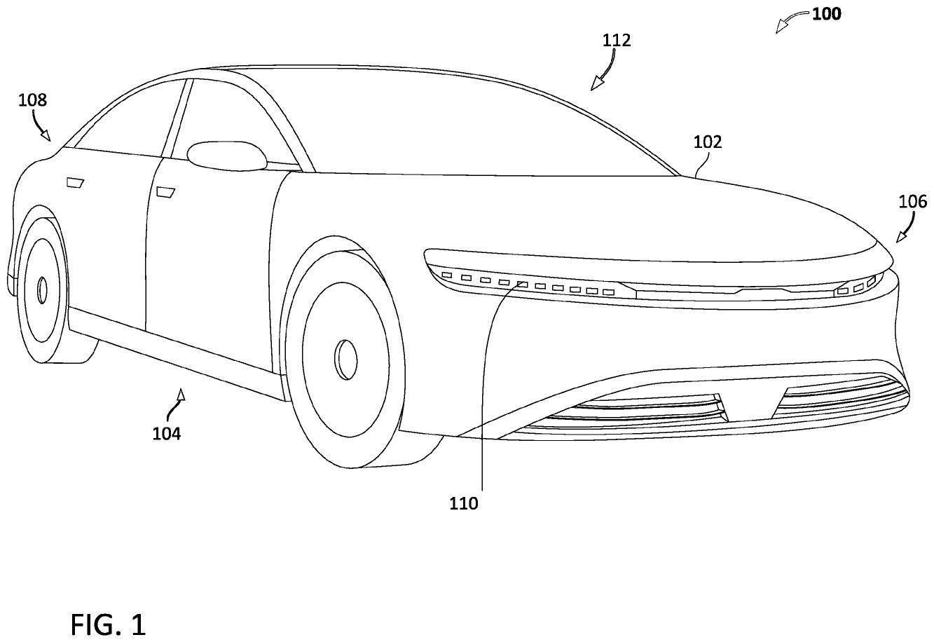

FIG. 1 shows an example of a vehicle 100. The vehicle 100 can be used with one or more other examples described elsewhere herein. The vehicle 100 includes a vehicle body 102 and a vehicle chassis 104 supporting the vehicle body 102. For example, the vehicle body 102 is here of a four-door type with room for at least four occupants, and the vehicle chassis 104 has four wheels. Other numbers of doors, types of vehicle body 102, and/or kinds of vehicle chassis 104 can be used in some implementations.

The vehicle body 102 has a front 106 and a rear 108 and can have a passenger cabin 112 between the front and the rear. The vehicle 100 can have at least one motor, which can be positioned in one or more locations of the vehicle 100. In some implementations, the motor(s) can be mounted generally near the front 106, generally near the rear 108, or both. A battery module can be supported by chassis 104, for example, below the passenger cabin and can be used to power the motor(s). The vehicle 100 can have at least one lighting component, which can be situated in one or more locations of the vehicle 100. For example, the vehicle 100 can have one or more headlights 110 mounted generally near the front 106.

The rear 108 of the vehicle 100 can include a trunk compartment, and the front 106 of the vehicle 100 can include a front trunk (a.k.a., frunk) compartment, each of which is outside the passenger cabin and each of which can be used for storage of vehicle components or personal equipment. For example, one or more electrical circuit modules, for example, as part of a HVJB, can be included within the trunk or the frunk can be used to manage the charging of the batteries in the battery module and to manage the distribution of electrical current from the battery module to the one or more motors in the vehicle. In modern electric vehicle having many battery cells and electrical connections a plurality of busbars may be used to manage the distribution of electrical energy to and from the battery cells of a battery module.

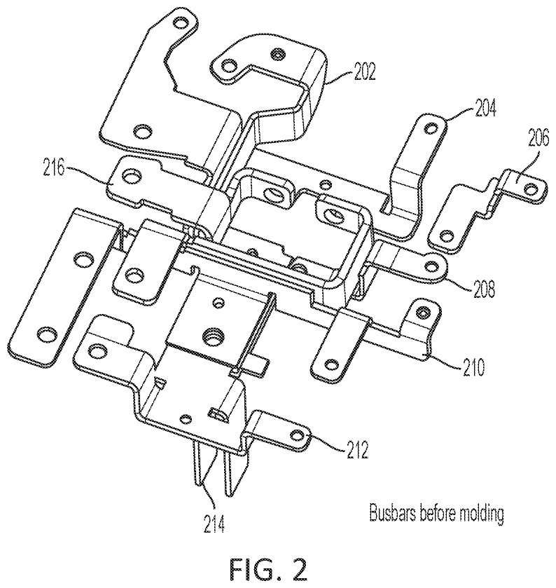

FIG. 2 is a schematic example arrangement of a plurality of separate busbars 202, 204, 206, 208 210, 212, 214, 216, 218, 220 that can be integrated into a modular component during production for assembly into the vehicle 100. The separate busbars 202, 204, 206, 208 210, 212, 214, 216, 218, 220 can be part of a HVJB that manages the distribution of electrical power from a charging source to a battery module and that manages the distribution of electrical power from the battery module to one or more components of the vehicle, which require electrical power for their operation, such as, for example, motors that power the drivetrain of the vehicle, HVAC components, heaters, etc. The separate busbars 202, 204, 206, 208 210, 212, 214, 216, 218, 220 can be electrically isolated from each other can provide an electrical conduit from one component (e.g., a battery cell) of the vehicle to another component (e.g., a motor or a charging station). Holes on the electrically conductive busbars can be used to connect (e.g., fasten) the busbar to another component.

FIG. 2 shows the busbars 202, 204, 206, 208 210, 212, 214, 216, 218, 220 as being mechanically disconnected from each other, but being located and oriented in their final positions in which they would be used in the vehicle.

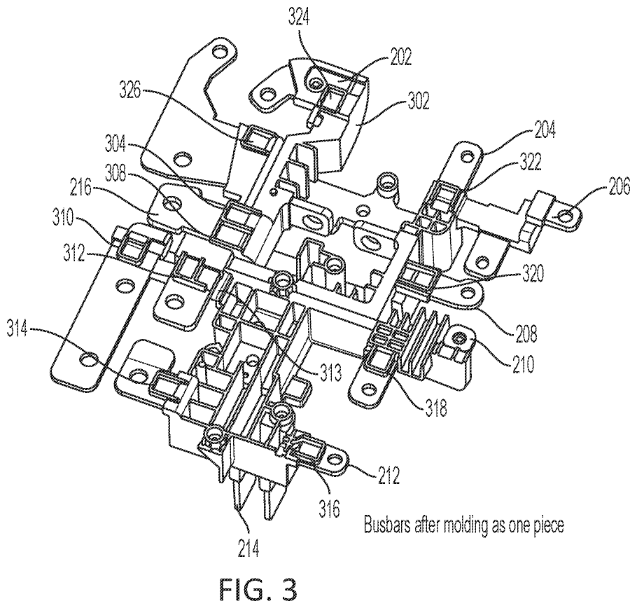

FIG. 3 is an example schematic diagram of the busbars 202, 204, 206, 208 210, 212, 214, 216, 218, 220 of FIG. 2 mechanically connected to each other after they have been overmolded with a polymer material 302 (e.g., a thermoplastic or thermosetting material). For example, the busbars 202, 204, 206, 208 210, 212, 214, 216, 218, 220 of FIG. 2 can be placed in a mold cavity and overmolded with the molten polymer material 302 and then cooled to allow the polymer material to harden and set into its final shape and form. During the molding process, the polymer material may be bonded to portions of the busbars 202, 204, 206, 208 210, 212, 214, 216, 218, 220, so that the busbars are rigidly held in place relative to each other by the set polymer material.

In some implementations, the overmolded polymer material 302, after it has set, can include one or more receptacles or holders 304, 306, 308, 310, 312, 314, 316, 318, 320, 322, 324, 326 formed from portions of the overmolded material 302 that are configured to receive one or more sensors that can be used to monitor a status or performance of the busbar. Sensors used to monitor a status or performance of the busbar can include, for example, thermistors for measuring a temperature of the busbar, voltage meters and current meters configured for measuring electrical properties of the busbar, strain gauges configured for measuring mechanical properties of the busbar, and the like.

The receptacles 304, 306, 308, 310, 312, 314, 316, 318, 320, 322, 324, 326 can be defined, for example, by one or more raised portions of the overmolded polymer material 302 that can define a shape that is complementary to a shape of the sensor to be received in the receptacle. For example, a receptacle 304, 306, 308, 310, 312, 314, 316, 318, 320, 322, 324, 326 can define a rectangular shape or a circular shape, etc.

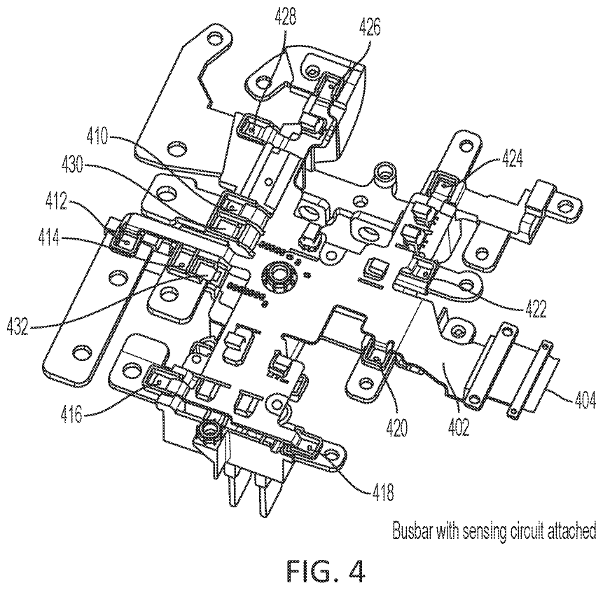

FIG. 4 is an example schematic diagram of the overmolded busbars shown in FIG. 3 when a flexible printed circuit board (“flex PCB”) 402 is attached to the busbars. For clarity, the busbars in FIG. 4 are not labeled, but they are the same as the busbars in FIG. 3. The flex PCB 402 can include a number of electrical components that are fabricated with or attached to the flex PCB 402 before the flex PCB is attached to the overmolded busbars. Connections to the electrical components can be provided through wires or conductive traces in the flex PCB 402, and the electrical components can be connected to an off-board controller (e.g., a central processing unit, an application specific integrated circuit, or the like) through a connector 404 (e.g., a ribbon connector).

The electrical components that are included with the flex PCB 402 can include one or more temperature sensors 410, 412, 414, 416, 418, 420, 422, 424, 426, 428. The temperature sensors can include, for example, negative temperature coefficient (NTC) thermistors that output a voltage that depends on a temperature of the sensor. The temperature sensors 410, 412, 414, 416, 418, 420, 422, 424, 426, 428 can be arranged on the flex PCB 402, such that when the flex PCB is attached to the overmolded busbar the temperature sensors are located within receptacles formed within the molded polymer material and are in thermal contact with one or more locations of individual busbars 202, 204, 206, 208 210, 212, 214, 216, 218, 220. Mechanical and thermal contact between a temperature sensor 410, 412, 414, 416, 418, 420, 422, 424, 426, 428 and the busbar can be achieved with an adhesive material having appropriate mechanical and thermal properties (e.g., having a relatively high thermal conductivity), such that a temperature measured by the temperature sensor is a close approximation of the temperature of the busbar.

The electrical components that are included with the flex PCB 402 also can include one or more voltage sensors 430, 432. The voltage sensors 430, 432 can be arranged on the flex PCB 402, such that when the flex PCB is attached to overmolded busbar, the voltage sensors are located within receptacles formed within the molded polymer material and are in electrical contact with one or more locations on individual busbars 202, 204, 206, 208 210, 212, 214, 216, 218, 220. Electrical and thermal contact between the 430, 432 can be achieved, for example, by laser welding contacts of the voltage sensors 430, 432 to the busbars 202, 204, 206, 208 210, 212, 214, 216, 218, 220. For example, the voltage sensors 430, 432 that are coupled to the flex PCB 402 can be positioned within receptacles formed by the polymer material 302 that is used to overmolded busbars, and then, once the voltage sensors are correctly positioned, laser light can be provided to the interface between the contacts of the voltage sensors and the busbars to weld the contacts of the voltage sensors to the busbars.

By providing the sensors 410, 412, 414, 416, 418, 420, 422, 424, 426, 428, 430, 432 on the flex PCB 402 prior to attaching the flex PCB to the overmolded busbar, the complexity of manufacturing the overmolded busbar can be significantly reduced. For example, individually attaching multiple thermistors to the busbars can be avoided, and instead the thermistors attached to the flex PCB can all be attached to the busbars at once. In addition, electrical connections between the sensors and a flex PCB can be made before the PCB is installed on the overmolded busbar thus, facilitating the fabrication of a device that otherwise would require numerous connections to be made in a complicated mechanical part.

The terms “substantially” and “about” used throughout this Specification are used to describe and account for small fluctuations, such as due to variations in processing. For example, they can refer to less than or equal to ±5%, such as less than or equal to ±2%, such as less than or equal to #1%, such as less than or equal to ±0.5%, such as less than or equal to ±0.2%, such as less than or equal to ±0.1%, such as less than or equal to ±0.05%. Also, when used herein, an indefinite article such as “a” or “an” means “at least one.”

It should be appreciated that all combinations of the foregoing concepts and additional concepts discussed in greater detail below (provided such concepts are not mutually inconsistent) are contemplated as being part of the inventive subject matter disclosed herein. In particular, all combinations of subject matter appearing in this disclosure are contemplated as being part of the inventive subject matter disclosed herein.

A number of implementations have been described. Nevertheless, it will be understood that various modifications may be made without departing from the spirit and scope of the specification.

In addition, the logic flows depicted in the figures do not require the particular order shown, or sequential order, to achieve desirable results. In addition, other processes may be provided, or processes may be eliminated, from the described flows, and other components may be added to, or removed from, the described systems.

While certain features of the described implementations have been illustrated as described herein, many modifications, substitutions, changes and equivalents will now occur to those skilled in the art. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

Systems and methods have been described in general terms as an aid to understanding details of the invention. In some instances, well-known structures, materials, and/or operations have not been specifically shown or described in detail to avoid obscuring aspects of the invention. In other instances, specific details have been given in order to provide a thorough understanding of the invention. One skilled in the relevant art will recognize that the invention may be embodied in other specific forms, for example to adapt to a particular system or apparatus or situation or material or component, without departing from the spirit or essential characteristics thereof. Therefore, the disclosures and descriptions herein are intended to be illustrative, but not limiting, of the scope of the invention.

1. A vehicle comprising:
a plurality of separate and distinct electrical busbars that are electrically isolated from each other;
a polymer overmold material that mechanically couples the separate and distinct electrical busbars to each other in a single integrated multi-busbar unit, wherein the overmold material is provided to the busbars through an injection molding process;
a flex printed circuit board having a plurality of sensors that is coupled to the single integrated multi-busbar unit, wherein the sensors are coupled to the distinct electrical busbars when the flex printed circuit board is coupled to the integrated busbar unit.

2. The vehicle of claim 1, wherein the sensors include a least one temperature sensor configured for measuring a temperature of at least one of the separate and distinct electrical busbars.

3. The vehicle of claim 1, wherein the sensors include at least one voltage sensor configured for measuring a voltage of at least one of the separate and distinct electrical busbars relative to a ground voltage.

4. The vehicle of claim 1, wherein the sensors include at least one strain gauge configured for measuring a mechanical property of at least one of the separate and distinct electrical busbars.

5. The vehicle of claim 1, wherein the flex printed circuit board includes a ribbon cable configured to establish electrical connections between the plurality of sensors and an off-board controller.

6. The vehicle of claim 1, wherein the busbars are part of a high voltage junction box.

7. The vehicle of claim 1, further comprising a battery module having a plurality of electrochemical cells, wherein the separate and distinct electrical busbars are configured for conducting electricity to the electrochemical cells.

8. An apparatus comprising:
a plurality of separate and distinct electrical busbars that are electrically isolated from each other; and
a polymer overmold material that mechanically couples the separate and distinct electrical busbars to each other in a single integrated multi-busbar unit, wherein the overmold material is provided to the busbars through an injection molding process;
wherein the single integrated multi-busbar unit is configured to be coupled to a flex printed circuit board having a plurality of sensors, such that the sensors are coupled to the distinct electrical busbars when the flex printed circuit board is coupled to the integrated busbar unit.

9. The apparatus of claim 8, wherein the polymer overmold material includes a plurality of receptacles configured for receiving the plurality of sensors.

10. The apparatus of claim 8, wherein the sensors include a least one temperature sensor configured for measuring a temperature of at least one of the separate and distinct electrical busbars.

11. The apparatus of claim 8, wherein the sensors include at least one voltage sensor configured for measuring a voltage of at least one of the separate and distinct electrical busbars relative to a ground voltage.

12. The apparatus of claim 8, wherein the sensors include at least one strain gauge configured for measuring a mechanical property of at least one of the separate and distinct electrical busbars.

13. The apparatus of claim 8, wherein the busbars are part of a high voltage junction box.

14. The apparatus of claim 13, wherein the electrical busbars include a plurality of holes configured for fastening the integrated multi-busbar unit to another component of the high voltage junction box.

15. A method of making an integrated multi-busbar unit, the method comprising:
placing a plurality of separate and distinct electrical busbars into a mold cavity;
injecting molten polymer material into the mold cavity,
setting the polymer material in the mold cavity, such that the set polymer material bonds to the separate and distinct electrical busbars and the separate and distinct electrical busbars are rigidly held in place in a configuration in which the separate and distinct electrical busbars are electrically isolated from each other,
wherein, after the polymer material is set, the integrated multi-busbar unit is configured to be coupled to a flex printed circuit board having a plurality of sensors, such that the sensors are coupled to the distinct electrical busbars when the flex printed circuit board is coupled to the integrated busbar unit.

16. The method of claim 15, wherein the set polymer overmold material includes a plurality of receptacles configured for receiving the plurality of sensors.

17. The method of claim 15, wherein the electrical busbars include a plurality of holes configured for fastening the integrated multi-busbar unit to another component.
